(19) United States
(12) Patent Application Publication
(10) Pub. No.: US 2023/0307224 A1
(43) Pub. Date: Sep. 28, 2023

(54) PARTICLE COLLECTING DEVICE AND DEPOSITION APPARATUS INCLUDING THE SAME

(71) Applicant: Samsung Display Co., Ltd., Yongin-si (KR)

(72) Inventors: SUNGJIN KIM, Asan-si (KR); CHUNYOUNG PARK, Yangju-si (KR); JAEMORK PARK, Asan-si (KR); WONSEOK CHO, Suwon-si (KR)

(21) Appl. No.: 18/123,206

(22) Filed: Mar. 17, 2023

(30) Foreign Application Priority Data
Mar. 25, 2022 (KR) 10-2022-0037156

(51) Int. Cl. H01L 21/02; H10K 71/16

(52) U.S. Cl. CPC H01L 21/02057; H10K 71/164

(57) ABSTRACT

A particle collecting device includes: a first collecting device to be located on a substrate transferred in a first direction, and extending in a second direction crossing the first direction; and a second collecting device adjacent to the first collecting device in the first direction, the second collecting device to be located on the substrate, and extending in the second direction. The first collecting device is to collect a first particle remaining on the substrate, and the second collecting device is to collect a second particle remaining on the substrate, the second particle including a material different from that of the first particle.

### CROSS-REFERENCE TO RELATED APPLICATIONS

This application claims priority to and the benefit of Korean Patent Application No. 10-2022-0037156, filed on Mar. 25, 2022, in the Korean Intellectual Property Office, the entire content of which is incorporated by reference herein.

### BACKGROUND

### 1. Field

Aspects of embodiments of the present disclosure relate to a particle collecting device, and a deposition apparatus including the same.

### 2. Description of the Related Art

In general, a display device includes a display panel for displaying an image. The display panel includes a plurality of elements that generate an image. When a display panel is manufactured, a metal thin film, an inorganic layer, an organic layer, and the like, which are used for forming various elements, are formed on a substrate by deposition processes.

The deposition processes are performed in a plurality of chambers, so that various elements are formed on a substrate. The substrate is transferred to different chambers, and various materials are deposited on the substrate. The substrate is transferred between chambers by a substrate carrier, and a mask is used when a deposition material is deposited on the substrate.

The above information disclosed in this Background section is for enhancement of understanding of the background of the present disclosure, and therefore, it may contain information that does not constitute prior art.

### SUMMARY

During a deposition process, various pollutant particles may remain on the substrate. For example, when the substrate, the substrate carrier, and the mask are transferred into different chambers, metal particles may occur due to a friction between structures (for example, the structures of an aligning device) in the chambers. In addition, during the deposition processes for an organic layer and an inorganic layer, organic particles and inorganic particles may occur. Such pollutant particles that remain on the substrate may cause a defect in a display panel.

One or more embodiments of the present disclosure are directed to a particle collecting device for preventing or substantially preventing a defect in a display panel, and a deposition apparatus including the same.

According to one or more embodiments of the present disclosure, a particle collecting device includes: a first collecting device configured to be located on a substrate transferred in a first direction, and extending in a second direction crossing the first direction; and a second collecting device adjacent to the first collecting device in the first direction, the second collecting device configured to be located on the substrate, and extending in the second direction. The first collecting device is configured to collect a first particle remaining on the substrate, and the second collecting device is configured to collect a second particle remaining on the substrate, the second particle including a material different from that of the first particle.

In an embodiment, the substrate may be configured to be transferred from a first chamber to a second chamber adjacent to the first chamber; an opening may be defined in the first chamber, the opening being a path through which the substrate is transferred; and the first and second collecting devices may be located on an inner wall of the first chamber adjacent to the opening.

In an embodiment, when the substrate is transferred from the first chamber to the second chamber by a robot arm, the first and second collecting devices may be configured to collect the first and second particles in the first chamber together.

In an embodiment, the first collecting device may be configured to generate a magnetic force.

In an embodiment, the first particle may include a metal particle.

In an embodiment, the second collecting device may be configured to generate an electrostatic force.

In an embodiment, the second particle may include an organic particle or an inorganic particle.

In an embodiment, the particle collecting device may further include a main frame, and the first and second collecting devices may be located underneath the main frame.

In an embodiment, the main frame may include a metal.

In an embodiment, the particle collecting device may further include: a first insulating layer between the main frame and the first collecting device; and a second insulating layer between the main frame and the second collecting device.

In an embodiment, the first collecting device may include: a case underneath the main frame; and at least one magnet in the case.

In an embodiment, the case may include a metal.

In an embodiment, the second collecting device may include: a sub frame underneath the main frame; an insulating layer underneath the sub frame; and a first electrode and a second electrode in the insulating layer, and configured to receive voltages of different polarities from each other.

In an embodiment, the sub frame may include a metal.

In an embodiment, the particle collecting device may further include a DC power supply configured to apply DC voltages to the first electrode and the second electrode.

In an embodiment, the substrate may be configured to be transferred from a first chamber to a second chamber adjacent to the first chamber; an opening may be defined in the second chamber, the opening being a path through which the substrate is transferred; and the first and second collecting devices may be located on an inner wall of the second chamber adjacent to the opening.

In an embodiment, the substrate may be configured to be transferred from a first chamber to a second chamber adjacent to the first chamber by a substrate carrier; a first opening and a second opening may be defined in the first chamber and the second chamber, respectively, the first opening and the second opening being paths through which the substrate is transferred; and the first collecting device may be located on an inner wall of the second chamber adjacent to the second opening, and the second collecting device may be located on an inner wall of the first chamber adjacent to the first opening.

According to one or more embodiments of the present disclosure a deposition apparatus includes: a first chamber; a second chamber adjacent to the first chamber; a first collecting device configured to be located on a substrate transferred from the first chamber to the second chamber; and a second collecting device configured to be located on the substrate, and adjacent to the first collecting device. An opening is defined in the first chamber, the opening being a path through which the substrate is transferred, the first and second collecting devices are located on an inner wall of the first chamber adjacent to the opening, the first collecting device is configured to collect a first particle remaining on the substrate, and the second collecting device is configured to collect a second particle remaining on the substrate, the second particle including a material different from that of the first particle.

In an embodiment, the first collecting device may be configured to generate a magnetic force, the first particle may include a metal particle, the second collecting device may be configured to generate an electrostatic force, and the second particle may include an organic particle or an inorganic particle.

In an embodiment, the first collecting device may include: a case; and at least one magnet in the case, and the second collecting device may include: a sub frame: an insulating layer underneath the sub frame; and a first electrode and a second electrode in the insulating layer, the first electrode and the second electrode being configured to receive voltages of different polarities from each other.

### BRIEF DESCRIPTION OF THE DRAWINGS

The above and other aspects and features of the present disclosure will be more clearly understood from the following detailed description of the illustrative, non-limiting embodiments with reference to the accompanying drawings. In the drawings:

FIG. 1 is a schematic diagram illustrating a configuration of a deposition apparatus including a particle collecting device according to an embodiment of the present disclosure;

FIG. 2 is a plan view of a display panel that may be manufactured using the deposition apparatus illustrated in FIG. 1;

FIG. 3 is a cross-section view illustrating a configuration of a pixel that may be manufactured by the deposition apparatus illustrated in FIG. 1;

FIG. 4 is a cross-sectional view illustrating a deposition process for an organic layer that forms a light-emitting element illustrated in FIG. 3;

FIG. 5 is a diagram illustrating a particle collecting device and a robot arm disposed in an inner space of a first chamber illustrated in FIG. 1;

FIG. 6 is a cross-sectional view taken along the line I-I′ in FIG. 5, and illustrates a configuration of the particle collecting device illustrated in FIG. 5;

FIG. 7 is a plan view of the robot arm illustrated in FIG. 5;

FIG. 8 is a cross-sectional view taken along the line II-II′ in FIG. 5, and illustrates a particle collecting operation of the particle collecting device illustrated in FIG. 5;

FIG. 9 is a diagram illustrating a configuration of a particle collecting device according to another embodiment of the present disclosure;

FIG. 10 is a diagram illustrating a configuration of a particle collecting device according to another embodiment of the present disclosure; and

FIG. 11 is a diagram in which the particle collecting devices illustrated in FIG. 10 are successively arranged in chambers.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

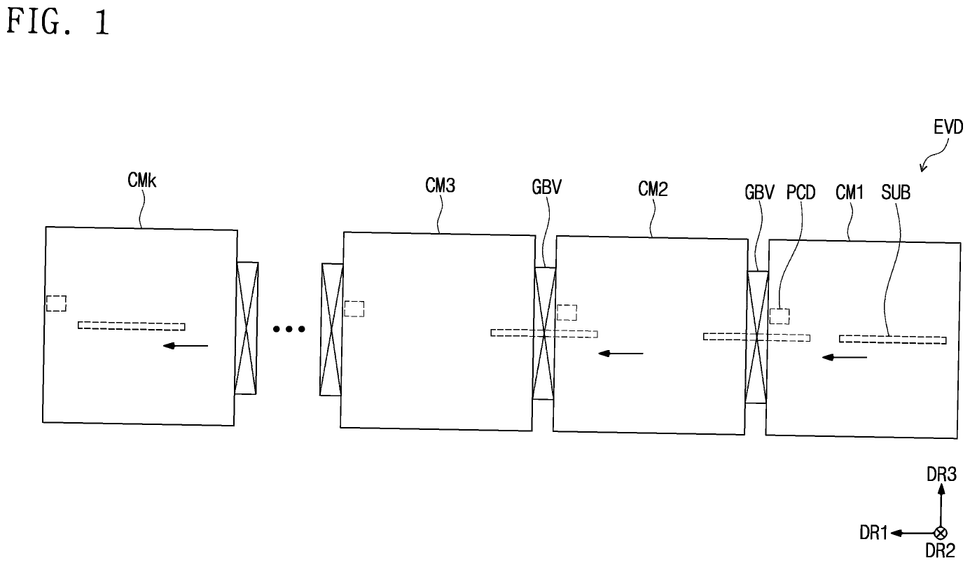

FIG. 1 is a schematic diagram illustrating a configuration of a deposition apparatus including a particle collecting device according to an embodiment of the present disclosure.

Referring to FIG. 1, a deposition apparatus EVD may include a plurality of chambers CM1 to CMk, a plurality of gate valves GBV disposed between the chambers CM1 to CMk, and a plurality of particle collecting devices PCD disposed in the chambers CM1 to CMk, where k is a natural number larger than 1.

The chambers CM1 to CMk may be defined as vacuum chambers. In addition, the chambers CM1 to CMk may be chambers to perform a deposition process. The chambers CM1 to CMk may be arranged along a first direction DR1. Deposition processes may be performed in the chambers CM1 to CMk. FIG. 1 illustrates side surfaces of the chambers CM1 to CMk when viewed in a second direction DR2 crossing the first direction DR1, as an example.

Hereinafter, a direction that vertically or substantially vertically crosses a plane defined by the first direction DR1 and the second direction DR2 is defined as a third direction DR3. In addition, as used in the present disclosure, the phrases “seen on a plane”, “viewed on a plane”, and “in a plan view” may refer to a view of a component, element, or layer in/from the third direction DR3.

Different deposition processes may be performed in the chambers CM1 to CMk. For example, an inorganic layer deposition process for forming an inorganic layer may be performed in one chamber from among the chambers CM1 to CMk. In addition, an organic layer deposition process for forming an organic layer may be performed in another chamber from among the chambers CM1 to CMk. In addition, a deposition process for forming a metal thin film may be performed in still another chamber from among the chambers CM1 to CMk.

The chambers CM1 to CMk may include first to k-th chambers CM1 to CMk. A substrate SUB that is used to perform a deposition process thereon may be transferred to the first chamber CM1, and a first deposition process may be performed on the substrate SUB in the first chamber CM1. FIG. 1 illustrates the substrate SUB disposed inside the chambers CM1 to CMk, and is depicted using a dotted line, as an example.

After the first deposition process is finished, the substrate SUB may be transferred from the first chamber CM1 to the second chamber CM2 in the first direction DR1. A second deposition process may be performed on the substrate SUB in the second chamber CM2.

A movement path to transfer (e.g., to move) the substrate SUB may be formed in the first chamber CM1 and the second chamber CM2. Such a movement path may be opened and closed by a gate valve GBV disposed between the first chamber CM1 and the second chamber CM2. When the movement path is opened by the gate valve GBV, the substrate SUB may be moved into the second chamber CM2.

Through such operations, first to k-th deposition processes may be performed in the first to k-th chambers CM1 to CMk. The first to k-th deposition processes may include an inorganic material deposition process, an organic material deposition process, and a metal thin film deposition process.

When the substrate SUB and a mask for performing a deposition process are transferred into the chambers CM1 to CMk, and the deposition processes are performed, various pollutant particles may occur. For example, when the substrate SUB and the mask are transferred into the chambers CM1 to CMk, friction may occur in structures for transferring the substrate SUB and the mask into the chambers CM1 to CMk, structures for transferring the substrate SUB and the mask vertically and horizontally, and/or structures for rotating the substrate SUB and the mask.

The chambers CM1 to CMk and the structures in the chambers CM1 to CMk may be formed of a metal. Accordingly, pollutant particles, such as metal particles, may occur due to friction. Such metal pollutant particles may be provided on the substrate SUB, and may remain on the substrate SUB.

In addition, when the inorganic layer deposition process and the organic layer deposition process described above are performed, pollutant particles, such as inorganic particles and organic particles, may occur. Such inorganic and organic pollutant particles may be provided on the substrate SUB, and may remain on the substrate SUB.

The pollutant particles that remain on the substrate SUB may cause a defect in a display panel manufactured using the substrate SUB. Accordingly, a yield of the display panel may be reduced.

In an embodiment of the present disclosure, the pollutant particles may be removed by particle collecting devices PCD. The particle collecting devices PCD may be disposed in the chambers CM1 to CMk, respectively. The particle collecting devices PCD may be disposed adjacent to parts of the chambers CM1 to CMk from which the substrate SUB is taken out (e.g., removed from the corresponding chamber). FIG. 1 illustrates the particle collecting devices PCD disposed in the chambers CM1 to CMk that are depicted using a dotted line, for example.

When the substrate SUB is transferred from an h-th chamber to a (h+1)-th chamber, the substrate SUB is taken out (e.g., removed) from the h-th chamber, and a h-th particle collecting device PCD may be disposed adjacent to a part of the h-th chamber from which the substrate SUB is taken out, where h is a natural number equal to or less than k. For example, the h-th particle collecting device PCD may be disposed on a part of the h-th chamber adjacent to a gate valve GBV disposed between the h-th chamber and the (h+1)-th chamber.

For example, in the case of the first and second chambers CM1 and CM2, the substrate SUB may be taken out (e.g., removed) from the first chamber CM1, and the particle collecting device PCD may be disposed on a part of the first chamber CM1 adjacent to the gate valve GBV between the first chamber CM1 and the second chamber CM2.

When the substrate SUB is taken out (e.g., removed) from the first chamber CM1, the particle collecting device PCD may be disposed on the substrate SUB. When the substrate SUB is taken out (e.g., removed) from the first chamber CM1, the particle collecting device PCD may collect pollutant particles that may remain on the substrate SUB. Such an operation will be described in more detail below.

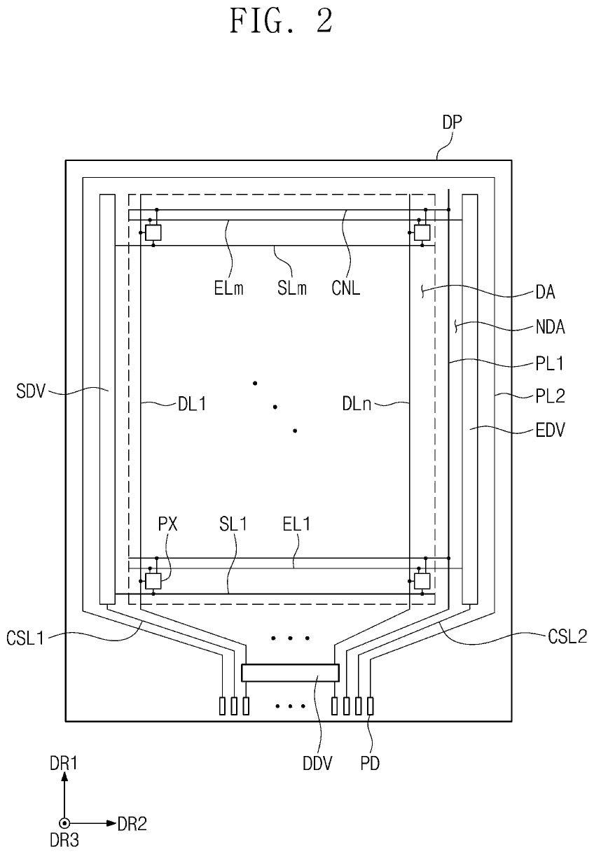

FIG. 2 is a plan view of a display panel that may be manufactured using the deposition apparatus illustrated in FIG. 1.

Referring to FIG. 2, a display panel DP may have a rectangular shape having long sides extending in the first direction DR1, and short sides extending in the second direction DR2, but the shape of the display panel DP is not limited thereto. The display panel DP may include a display region DA, and a non-display region NDA surrounding (e.g., around a periphery of) the display region DA.

The display panel DP may be a light-emitting display panel. The display panel DP may be an organic light-emitting display panel, or an inorganic light-emitting display panel. A light-emitting layer of the organic light-emitting display panel may include an organic light-emitting material. A light-emitting layer of the inorganic light-emitting display panel may include quantum dots, quantum rods, and/or the like. Hereinafter, for convenience, the display panel DP will be described in more detail in the context of an organic light-emitting display panel, but the present disclosure is not limited thereto.

The display panel DP may include a plurality of pixels PX, a plurality of scanning lines SL1 to SLm, a plurality of data lines DL1 to DLn, a plurality of light-emitting lines EL1 to ELm, first and second control lines CSL1 and CSL2, first and second power lines PL1 and PL2, connection lines CNL, and a plurality of pads PD, where m and n are natural numbers. The pixels PX may be manufactured on the aforementioned substrate SUB.

The pixels PX may be disposed at (e.g., in or on) the display region DA. A scan driver SDV and a light emission driver EDV may be disposed at (e.g., in or on) the non-display region NDA adjacent to the long sides of the display panel DP. A data driver DDV may be disposed at (e.g., in or on) the non-display region NDA adjacent to any one of the short sides of the display panel DP. When seen on a plane (e.g., in a plan view), the data driver DDV may be adjacent to a lower end of the display panel DP.

The scanning lines SL1 to SLm may extend in the second direction DR2, and may be connected to the pixels PX and the scan driver SDV. The data lines DL1 to DLn may extend in the first direction DR1, and may be connected to the pixels PX and the data driver DDV. The light-emitting lines EL1 to ELm may extend in the second direction DR2, and may be connected to the pixels PX and the light emission driver EDV.

A first power line PL1 may extend in the first direction DR1, and may be disposed at (e.g., in or on) the non-display region NDA. The first power line PL1 may be disposed between the display region DA and the light emission driver EDV, but the present disclosure is not limited thereto. For example, the first power line PL1 may be disposed between the display region DA and the scan driver SDV.

The connection lines CNL may extend in the second direction DR2, and may be arranged along the first direction DR1. The connection lines CNL may be connected to the first power line PL1 and the pixels PX. A first voltage may be applied to the pixels PX through the first power line PL1 and the connection lines CNL that are connected to each other.

A second power line PL2 may be disposed at (e.g., in or on) the non-display region NDA. The second power line PL2 may extend along the long sides of the display panel DP, and along another short side of the display panel DP at (e.g., in or on) which the data driver DDV is not disposed. The second power line PL2 may be disposed outside the scan driver SDV and the light emission driver EDV.

The second power line PL2 may extend to the display region DA, and may be connected to the pixels PX. A second voltage having a lower level than that of the first voltage may be applied to the pixels PX through the second power line PL2.

A first control line CSL1 may be connected to the scan driver SDV, and may extend to a lower end of the display panel DP, when seen on a plane (e.g., in a plan view). A second control line CSL2 may be connected to the light emission driver EDV, and may extend to a lower end of the display panel DP, when seen on a plane (e.g., in a plan view). The data driver DDV may be disposed between the first control line CSL1 and the second control line CSL2.

The pads PD may be disposed on the display panel DP. The pads PD may be more adjacent (e.g., closer) to a lower end of the display panel DP than the data driver DDV. The data driver DDV, the first power line PL1, the second power line PL2, the first control line CSL1, and the second control line CSL2 may be connected to the pads PD. The data lines DL1 to DLn may be connected to the data driver DDV, and the data driver DDV may be connected to the pads PD corresponding to the data lines DL1 to DLn.

A timing controller for controlling operations of the scan driver SDV, the data driver DDV, and the light emission driver EDV, and a voltage generating part for generating the first and second voltages, may be disposed on a printed circuit board. The timing controller and the voltage generating part may be connected to corresponding ones of the pads PD through the printed circuit board.

The scan driver SDV may generate a plurality of scanning signals, and the scanning signals may be applied to the pixels PX through the scanning lines SL1 to SLm. The data driver DDV may generate a plurality of data voltages, and the data voltages may be applied to the pixels PX through the data lines DL1 to DLn. The light emission driver EDV may generate a plurality of light-emitting signals, and the light-emitting signals may be applied to the pixels PX through the light-emitting lines EL1 to ELm.

The pixels PX may be provided with the data voltages in response to the scanning signals. The pixels PX may display an image by emitting light having luminances corresponding to the data voltages in response to the light-emitting signals. A light emission time of the pixels PX may be controlled by the light-emitting signals.

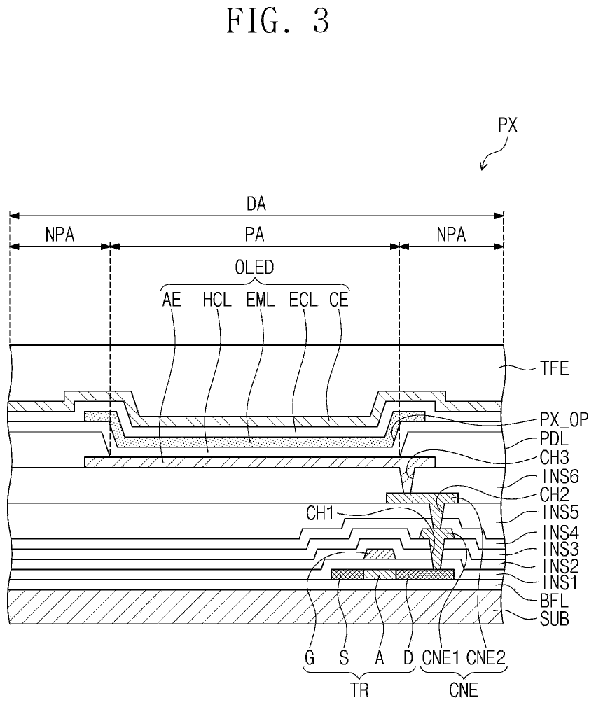

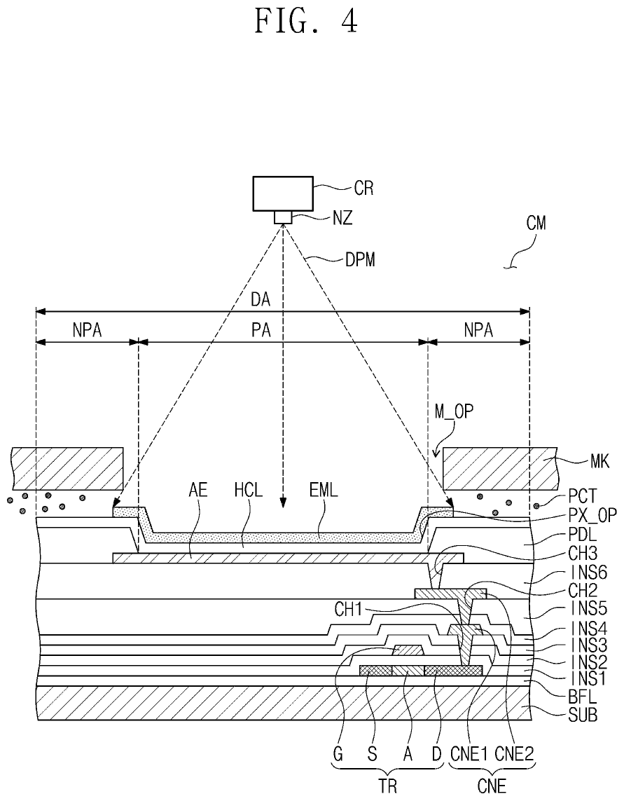

FIG. 3 is a cross-sectional view illustrating a configuration of a pixel that may be manufactured by the deposition apparatus illustrated in FIG. 1. FIG. 4 is a cross-sectional view illustrating a deposition process for an organic layer that forms the light-emitting element illustrated in FIG. 3.

Referring to FIG. 3, the pixels PX illustrated in FIG. 2 may each have a structure that is the same or substantially the same as that of the pixel PX illustrated in FIG. 3. The pixel PX may be disposed on a substrate SUB, and may include a transistor TR and a light-emitting element OLED.

The light-emitting element OLED may be an organic light-emitting element. The light-emitting element OLED may include a first electrode AE, a second electrode CE, a hole control layer HCL, an electron control layer ECL, and a light-emitting layer EML. The first electrode AE may be an anode, and the second electrode CE may be a cathode.

The transistor TR and the light-emitting element OLED may be disposed on the substrate SUB. One transistor TR is illustrated as an example, but the pixel PX may include a plurality of transistors and at least one capacitor for driving the light-emitting element OLED, in some embodiments.

The display region DA may include a light-emitting region PA corresponding to the pixel PX, and a non-light-emitting region NPA around (e.g., adjacent to) the light-emitting region PA. The light-emitting element OLED may be disposed at (e.g., in or on) the light-emitting region PA.

A buffer layer BFL may be disposed on the substrate SUB, and the buffer layer BFL may be an inorganic layer. A semiconductor pattern may be disposed on the buffer layer BFL. The semiconductor pattern may include polysilicon, but the present disclosure is not limited thereto. For example, the semiconductor pattern may include amorphous silicon or a metal oxide.

The semiconductor pattern may be doped with an N-type dopant or a P-type dopant. The semiconductor pattern may include a heavily doped region and a lightly doped region. The heavily doped region may have a higher conductivity than that of the lightly doped region, and may serve as a source electrode and/or a drain electrode of the transistor TR. The lightly doped region may correspond to or substantially correspond to an active A (e.g., a channel) of the transistor TR.

A source S, the active A, and a drain D of the transistor TR may be formed from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connection electrode CNE may be disposed between the transistor TR and the light-emitting element OLED, and may connect the transistor TR and the light-emitting element OLED to each other. The connection electrode CNE may include a first connection electrode CNE1 and a second connection electrode CNE2.

The first connection electrode CNE1 may be disposed on the third insulating layer INS3, and may be connected to the drain D through a first contact hole CH1 defined in (e.g., penetrating) the first to third insulating layers INS1 to INS3. A fourth insulating layer INS4 may be disposed on the first connection electrode CNE1. A fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 through a second contact hole CH2 defined in (e.g., penetrating) the fifth insulating layer INS5 and the fourth insulating layer INS4. A sixth insulating layer INS6 may be disposed on the second connection electrode CNE2. Each of the first insulating layer INS1 through the sixth insulating layer INS6 may be an inorganic layer or an organic layer.

The first electrode AE may be disposed on the sixth insulating layer INS6. The first electrode AE may be connected to the second connection electrode CNE2 through a third contact hole CH3 defined in (e.g., penetrating) the sixth insulating layer INS6. A pixel-defining film PDL exposing a part (e.g., a predetermined part) of the first electrode AE may be disposed on the first electrode AE and the sixth insulating layer INS6. A pixel opening PX_OP for exposing the part (e.g., the predetermined part) of the first electrode AE may be defined in the pixel-defining film PDL.

The hole control layer HCL may be disposed on the first electrode AE and the pixel-defining film PDL. The hole control layer HCL may be disposed at (e.g., in or on) the light-emitting region PA and the non-light-emitting region NPA in common. The hole control layer HCL may include a hole transport layer and a hole injection layer.

The light-emitting layer EML may be disposed on the hole control layer HCL. The light-emitting layer EML may be disposed at (e.g., in or on) a region corresponding to the pixel opening PX_OP. The light-emitting layer EML may include an organic material. The light-emitting layer EML may generate any suitable light from among red light, green light, and blue light.

The electron control layer ECL may be disposed on the light-emitting layer EML and the hole control layer HCL. The electron control layer ECL may be disposed at (e.g., in or on) the light-emitting region PA and the non-light-emitting region NPA in common. The electron control layer ECL may include an electron transport layer and an electron injection layer.

The second electrode CE may be disposed on the electron control layer ECL. The second electrode CE may be disposed in the pixels PX in common.

A thin-film encapsulation layer TFE may be disposed on the light-emitting element OLED. The thin-film encapsulation layer TFE may be disposed on the second electrode CE to cover the pixel PX. The thin-film encapsulation layer TFE may include at least two inorganic layers, and an organic layer between the inorganic layers. The inorganic layer may protect the pixel PX from moisture/oxygen. The organic layer may protect the pixel PX from foreign matter, such as dust particles.

A first voltage may be applied to the first electrode AE through the transistor TR, and a second voltage having a lower level than that of the first voltage may be applied to the second electrode CE. Holes and electrons injected into the light-emitting layer EML combine with each other to form excitons, and when the excitons transition to a ground state, the light-emitting element OLED may emit light.

Referring to FIGS. 3 and 4, a mask MK may be disposed above the substrate SUB in a chamber CM, and a crucible CR filled with a deposition material DPM may be disposed over the mask MK. The chamber CM may be any one of the chambers CM1 to CMk illustrated in FIG. 1.

The mask MK and the crucible CR may be components of the deposition apparatus EVD. An opening M_OP overlapping with the light-emitting region PA may be defined in the mask MK. The opening M_OP may overlap with the pixel opening PX_OP.

The deposition material DPM may be provided on the substrate SUB. For example, the deposition material DPM may be vaporized in the crucible CR disposed over the substrate SUB, and may then be sprayed onto the substrate SUB through a nozzle NZ connected to the crucible CR.

The deposition material DPM may be provided on the substrate SUB through the opening M_OP defined in the deposition mask MK. The deposition material DPM may be provided to the pixel opening PX_OP. The deposition material DPM may include an organic material for forming the light-emitting layer EML. Accordingly, the light-emitting layer EML, which is an organic layer, may be formed on the substrate SUB by the deposition material DPM.

An organic layer deposition process for forming the light-emitting layer EML is described as an example, but the present disclosure is not limited thereto. For example, an inorganic layer deposition process may be performed in other chambers. For example, in any one chamber CM1 to CMk illustrated in FIG. 1, an inorganic material used for forming the buffer layer BFL, which is an inorganic layer, may be provided on the substrate SUB.

During a deposition process, pollutant particles PCT may occur, diffuse, and/or remain on the substrate SUB in the chamber CM. The pollutant particles PCT illustrated in FIG. 4 may be organic particles. Such pollutant particles PCT may be collected by the particle collecting device PCD described above.

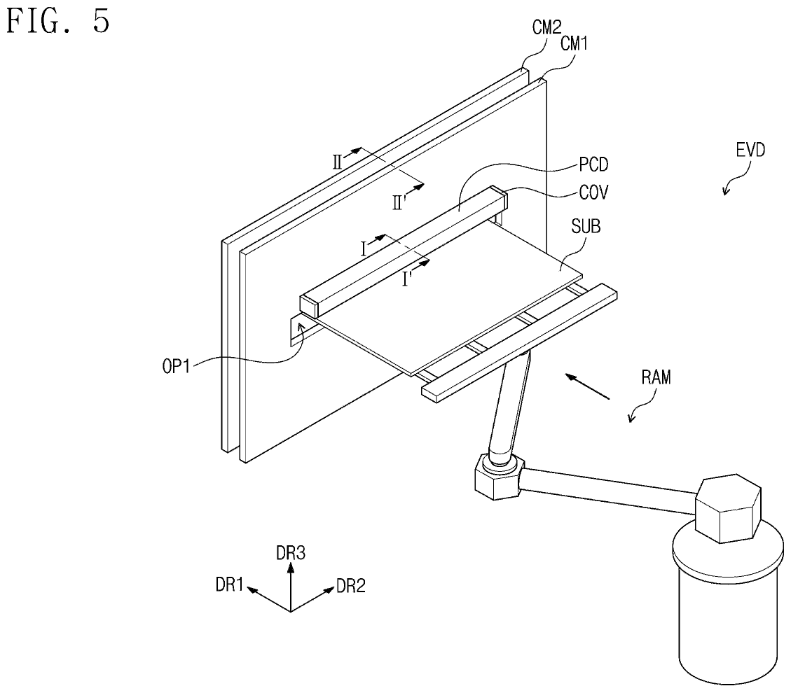

FIG. 5 is a diagram illustrating a particle collecting device and a robot arm disposed in an inner space of the first chamber illustrated in FIG. 1.

FIG. 5 illustrates, as an example, walls of the first and second chambers CM1 and CM2 that are adjacent to each other in the first direction DR1.

Referring to FIGS. 1 and 5, a first opening OP1 may be defined in the wall of the first chamber CM1 adjacent to the wall of the second chamber CM2. Corresponding openings may also be defined in the wall of the second chamber CM2 adjacent to the first chamber CM1, and in a gate valve GBV between the first and second chambers CM1 and CM2. The openings may provide a path for transferring the substrate SUB therethrough.

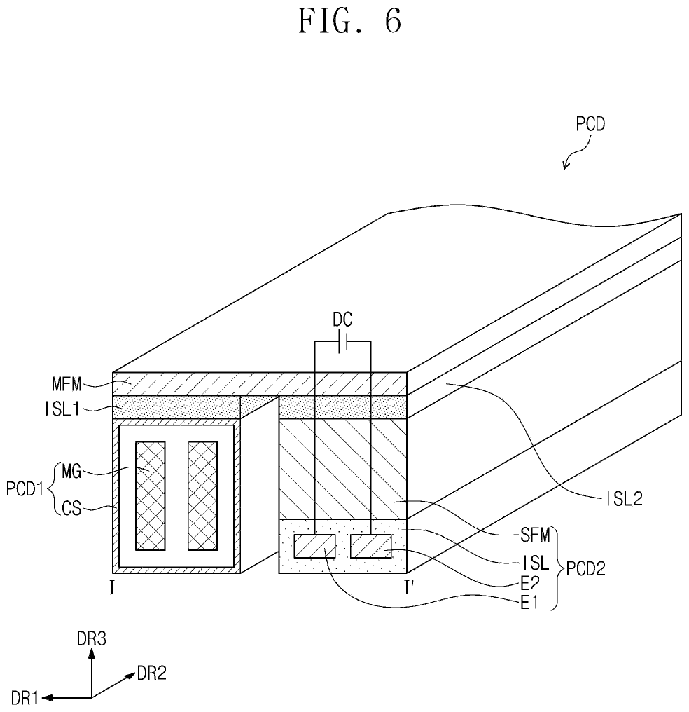

A particle collecting device PCD and a robot arm RAM may be disposed in the first chamber CM1. The particle collecting device PCD may extend in the second direction DR2. Cover parts COV may be disposed in the second direction DR2 on both opposite sides of the particle collecting device PCD. Both opposite sides of the particle collecting device PCD may be covered by the cover parts COV. A configuration of the particle collecting device PCD will be described in more detail below with reference to FIG. 6.

The particle collecting device PCD may be disposed adjacent to the first opening OP1 from which the substrate SUB is taken out. The particle collecting device PCD may be disposed on an inner wall of the first chamber CM1 adjacent to the first opening OP1.

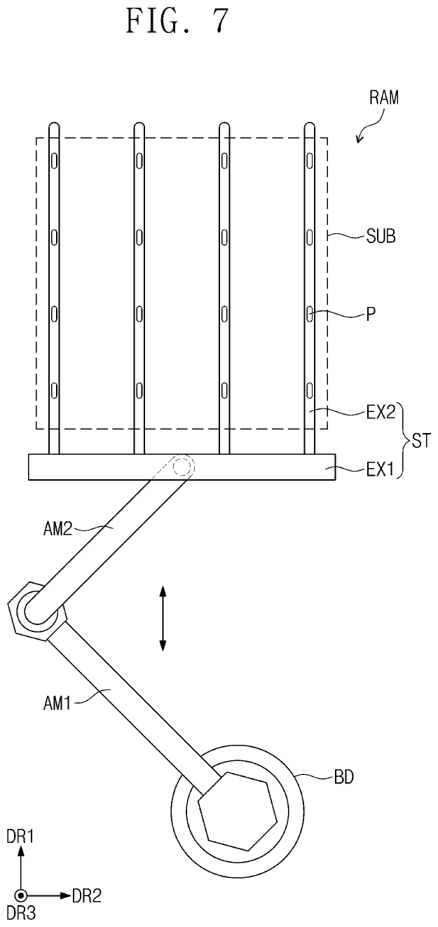

The robot arm RAM may expand and contract in the first direction DR1. The substrate SUB may be disposed on the robot arm RAM, and may be transferred in the first direction DR1 by the robot arm RAM. The substrate SUB may be taken out (e.g., removed) from the first chamber CM1 by the robot arm RAM, and may be transferred to enter the second chamber CM2 through the first opening OP1. The substrate SUB may be taken out from the first chamber CM1 through the first opening OP1 defined in the first chamber CM1. The structure of the robot arm RAM will be described in more detail below with reference to FIG. 7.

A robot arm, which is the same or substantially the same as the robot arm RAM illustrated in FIG. 5, may be disposed in the second chamber CM2. The substrate SUB transferred to the inside of the second chamber CM2 may be mounted on the robot arm disposed in the second chamber CM2.

The particle collecting device PCD may be disposed on the substrate SUB. When the substrate SUB is transferred from the first chamber CM1 to the second chamber CM2 by the robot arm RAM, the particle collecting device PCD may collect pollutant particles that may remain on the substrate SUB. Such an operation will be described in more detail below.

The length of the particle collecting device PCD in the second direction DR2 may be greater than at least the width of the substrate SUB in the second direction DR2. The particle collecting device PCD may sufficiently cover a region of the substrate SUB in the second direction DR2, thereby making it possible to easily collect the pollutant particles that may remain on the substrate SUB.

FIG. 6 is a cross-sectional view taken along the line I-I′ in FIG. 5, and illustrates a configuration of the particle collecting device illustrated in FIG. 5.

FIG. 6 illustrates, as an example, a perspective view of the cross-section of the particle collecting device PCD.

Referring to FIGS. 5 and 6, the particle collecting device PCD may include a main frame MFM, first and second insulating layers ISL1 and ISL2, a first collecting device PCD1, and a second collecting device PCD2.

The main frame MFM may extend longer in the second direction DR2 than in the first direction DR1. The main frame MFM may have a plane defined by the first and second directions DR1 and DR2.

The first and second insulating layers ISL1 and ISL2, the first collecting device PCD1, and the second collecting device PCD2 may be disposed under (e.g., underneath) the main frame MFM. The main frame MFM may include a metal. For example, the main frame MFM may be an aluminum frame.

The first insulating layer ISL1 may be disposed between the main frame MFM and the first collecting device PCD1. The second insulating layer ISL2 may be disposed between the main frame MFM and the second collecting device PCD2. The first and second insulating layers ISL1 and ISL2 may extend longer in the second direction DR2 than in the first direction DR1.

The first and second insulating layers ISL1 and ISL2 may be spaced apart from each other in the first direction DR1. The main frame MFM and the first and second collecting devices PCD1 and PCD2 may be insulated from each other by the first and second insulating layers ISL1 and ISL2.

The first and second collecting devices PCD1 and PCD2 may extend longer in the second direction DR2 than in the first direction DR1. The first and second collecting devices PCD1 and PCD2 may be spaced apart from each other in the first direction DR1.

The first collecting device PCD1 may generate a magnetic force. The second collecting device PCD2 may generate an electrostatic force. As described above, the lengths of the first and second collecting devices PCD1 and PCD2 in the second direction DR2 may be greater than at least the width of the substrate SUB in the second direction DR2.

The first collecting device PCD1 may include a case CS disposed under (e.g., underneath) the main frame MFM, and at least one magnet unit (e.g., magnet) MG disposed in the case CS. The first insulating layer ISL1 may be disposed between the case CS and the main frame MFM. The case CS may include a metal. For example, the case CS may include stainless steel (SUS304).

FIG. 6 illustrates, as an example, two magnet units (e.g., two magnets) MG, but the number of the magnet units MG is not limited thereto. The magnet units MG may include a ferromagnetic body. The magnet units MG may be disposed in an inner space of the case CS. The first collecting device PCD1 may generate a magnetic force due to the magnet units MG.

Suitable structures for fixing the magnet units MG may be disposed in the case CS.

The second collecting device PCD2 may include a sub frame SFM disposed under (e.g., underneath) the main frame MFM, an insulating layer ISL disposed under (e.g., underneath) the sub frame SFM, and a first electrode E1 and a second electrode E2 disposed in the insulating layer ISL.

The second insulating layer ISL2 may be disposed between the sub frame SFM and the main frame MFM. The sub frame SFM may include a metal. For example, the sub frame SFM may be an aluminum frame.

The first electrode E1 and the second electrode E2 may be spaced apart from each other in the first direction DR1, and thus, may receive voltages of different polarities from each other. A DC power supply may apply DC voltages to the first electrode E1 and the second electrode E2. A positive voltage (e.g., + voltage) may be applied to the first electrode E1, and a negative voltage (e.g., − voltage) may be applied to the second electrode E2. An electrostatic force may be generated in the second collecting device PCD2 due to the first electrode E1 and the second electrode E2.

FIG. 7 is a plan view of the robot arm illustrated in FIG. 5.

FIG. 7 illustrates, as an example, a substrate SUB using a dotted line.

Referring to FIGS. 5 and 7, the robot arm RAM may include a body BD, a first arm AM1, a second arm AM2, a substrate mounter ST, and a plurality of pads P. The body BD may have a cylindrical shape extending in the third direction DR3.

The first arm AM1 may be connected to the body BD. One end of the first arm AM1 may be rotatably connected to the body BD. The one end of the first arm AM1 may rotate about a rotational axis that is parallel to or substantially parallel to the third direction DR3.

The second arm AM2 may be connected to the first arm AM1. One end of the second arm AM2 may be rotatably connected to the other end of the first arm AM1. The one end of the second arm AM2 may rotate about a rotational axis that is parallel to or substantially parallel to the third direction DR3.

The first arm AM1 and the second arm AM2 may be foldably connected to each other. The first arm AM1 and the second arm AM2, which are foldably connected to each other, may move in the first direction DR1 to be expanded and contracted from each other.

The other end of the second arm AM2 may be connected to the substrate mounter ST. The substrate mounter ST may be rotatably connected to the other end of the second arm AM2. The substrate mounter ST may rotate about a rotational axis that is parallel to or substantially parallel to the third direction DR3.

The substrate SUB may be disposed on the substrate mounter ST to be transferred by the substrate mounter ST. While the first arm AM1, the second arm AM2, and the substrate mounter ST are driven to rotate relative to each other, the first arm AM1 and the second arm AM2 may be expanded and contracted in the first direction DR1. As the first arm AM1 and the second arm AM2 are expanded and contracted in the first direction DR1, the substrate SUB disposed on the substrate mounter ST may be transferred in the first direction DR1.

The substrate mounter ST may include a first extension part EX1 extending in the second direction DR2, and a plurality of second extension parts EX2 extending in the first direction DR1. The second extension parts EX2 may be arranged along the second direction DR2, and may be connected to the first extension part EX1. The substrate SUB may be disposed on the second extension parts EX2.

The pads P may be disposed on the second extension parts EX2. The pads P may be arranged along the first direction DR1 on each of the second extension parts EX2. The substrate SUB may be disposed on the pads P. The pads P may include an elastic material, such as rubber.

When the substrate SUB directly contacts the second extension parts EX2, the substrate SUB may be damaged. Because the substrate SUB is disposed on the pads PD formed of an elastic material, the substrate SUB may be prevented or substantially prevented from being damaged.

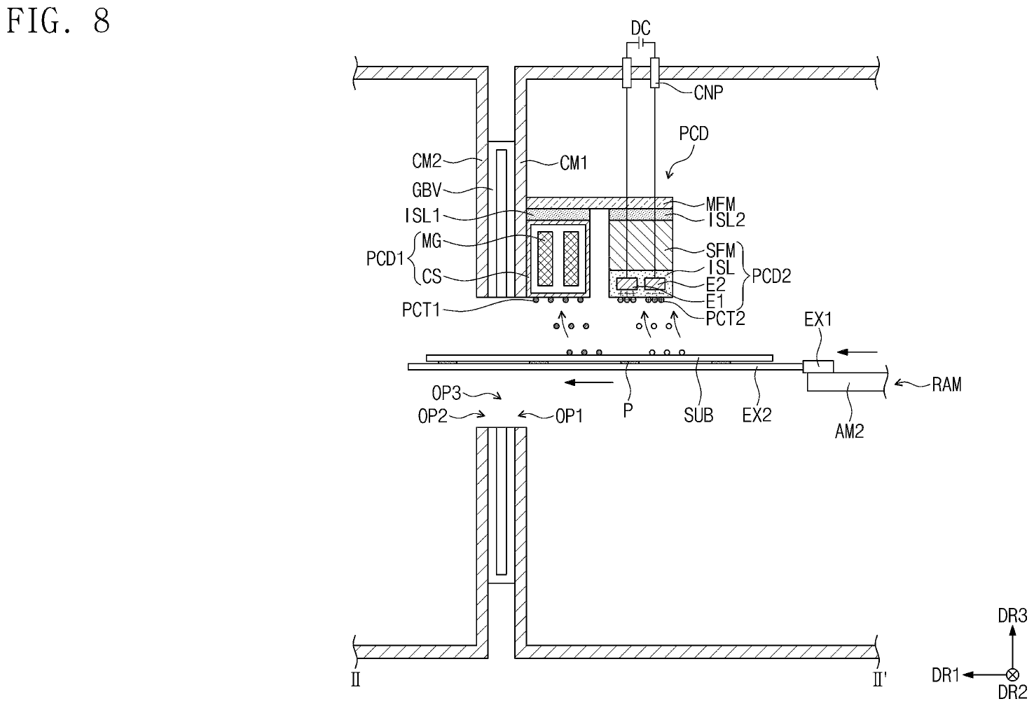

FIG. 8 is a cross-sectional view taken along the line II-II′ in FIG. 5, and illustrates a particle collecting operation of the particle collecting device illustrated in FIG. 5.

Referring to FIGS. 5 and 8, the first opening OP1 may be defined in a wall of the first chamber CM1 adjacent to a wall of the second chamber CM2. A second opening OP2 may be defined in the wall of the second chamber CM2 adjacent to the wall of the first chamber CM1.

A third opening OP3 may be defined in the gate valve GBV disposed between the first chamber CM1 and the second chamber CM2. The first, second, and third openings OP1, OP2, and OP3 may be formed in an integrated space. The first, second, and third openings OP1, OP2, and OP3 may be defined as a transfer path for the substrate SUB.

A space between the first chamber CM1 and the second chamber CM2 may be opened and closed by the gate valve GBV. For example, a partition wall disposed in the gate valve GBV may be driven in the third direction DR3, so that the third opening OP3 may be opened or closed.

The particle collecting device PCD may be connected to an inner wall of the first chamber CM1 adjacent to the first opening OP1. The particle collecting device PCD may be connected to the inner wall of the first chamber CM1 disposed above the first opening OP1. The main frame MFM of the particle collecting device PCD may be connected to the inner wall of the first chamber CM1, so that the particle collecting device PCD may be connected to the first chamber CM1.

The first and second collecting devices PCD1 and PCD2 may be disposed on the inner wall of the first chamber CM1 adjacent to the first opening OP1. The first and second collecting devices PCD1 and PCD2 may be disposed above the first opening OP1. The second collecting device PCD2 may be adjacent to the first collecting device PCD1 in the first direction DR1. The first collecting device PCD1 may be more adjacent (e.g., closer) to the inner wall of the first chamber CM1 than the second collecting device PCD2.

The second collecting device PCD2 may be connected to a DC power supply DC disposed outside of the first chamber CM1 through connection parts CNP. The connection parts CNP may be connected to an upper wall of the first chamber CM1 disposed on the second collecting device PCD2. The connection parts CNP may connect the second collecting device PCD2 disposed inside the first chamber CM1, which is in a vacuum state, to the DC power supply DC disposed outside the first chamber CM1, which is in a stand-by state. Lines connected to the DC power supply DC may extend to the inside of the first chamber CM1 through the connection parts CNP, and thus, may be connected to the second collecting device PCD2. The connection parts CNP may be defined as an electrical feedthrough.

After a deposition process is performed on the substrate SUB in the first chamber CM1, the substrate SUB may be transferred in the first direction DR1 by the robot arm RAM. The substrate SUB may be transferred from the first chamber CM1 to the second chamber CM2 through the first, second, and third openings OP1, OP2, and OP3. When the substrate SUB is transferred in the first direction DR1 through the first, second, and third openings OP1, OP2, and OP3, the first and second collecting devices PCD1 and PCD2 may be disposed on the substrate SUB.

First particles PCT1, and second particles PCT2 including a material different from that of the first particles PCT1, may remain on the substrate SUB. The first and second particles PCT1 and PCT2 may be pollutant particles as described above. For example, the first particles PCT1 may include metal particles as described above, and the second particles PCT2 may include inorganic particles or organic particles as described above.

When the substrate SUB is transferred in the first direction DR1, the first and second collecting devices PCD1 and PCD2 may collect both the first and second particles PCT1 and PCT2 in the first chamber CM1. The first collecting device PCD1 may collect the first particles PCT1 using a magnetic force generated by the magnet units MG of the first collecting device PCD1. The second collecting device PCD2 may collect the second particles PCT2 using an electrostatic force generated by the first and second electrodes E1 and E2.

The first particles PCT1 may be adsorbed onto a lower part of the case CS of the first collecting device PCD1. The second particles PCT2 may be adsorbed onto a lower part of the insulating layer ISL of the second collecting device PCD2. Accordingly, when the substrate SUB is transferred, the first and second particles PCT1 and PCT2 that may remain on the substrate SUB, which has been subjected to a first deposition process, may be removed together by the first and second collecting devices PCD1 and PCD2.

For example, a removal operation of the first and second particles PCT1 and PCT2 in the first and second chambers CM1 and CM2 has been described, but the same or substantially the same operation may also be performed in the second to k-th chambers CM2 to CMk.

In an embodiment of the present disclosure, when the substrate SUB is transferred through the first opening OP1, the particle collecting device PCD may concurrently (e.g., simultaneously) collect the metal particles and the organic and/or inorganic particles that may remain on the substrate SUB. Accordingly, when a display panel DP is manufactured, a defect in the display panel DP may be prevented or substantially prevented.

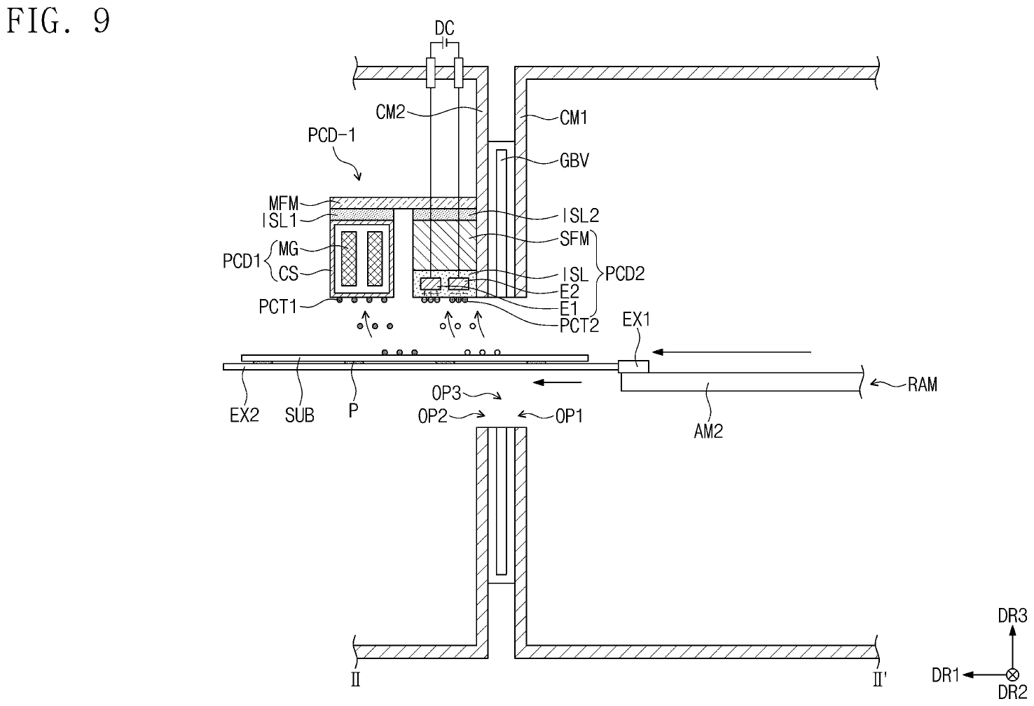

FIG. 9 is a diagram illustrating a configuration of a particle collecting device according to another embodiment of the present disclosure.

FIG. 9 illustrates, as an example, a cross-section corresponding to that shown in FIG. 8, and thus, redundant description of the particle collecting device PCD-1 illustrated in FIG. 9 as that of the particle collecting device PCD illustrated in FIG. 8 may not be repeated, and the differences therebetween may be mainly described hereinafter.

Referring to FIG. 9, unlike the particle collecting device PCD shown in FIG. 8, the particle collecting device PCD-1 may be disposed in the second chamber CM2. The particle collecting device PCD-1 may be connected to the inner wall of the second chamber CM2 adjacent to the second opening OP2 defined in the second chamber CM2. Accordingly, the first and second collecting devices PCD1 and PCD2 may be disposed on the inner wall of the second chamber CM2 adjacent to the second opening OP2. As described above, the second collecting device PCD2 may be connected to the DC power supply DC disposed outside the second chamber CM2 through the connection parts CNP.

When the substrate SUB is transferred from the first chamber CM1 to the second chamber CM2 by the robot arm RAM, the first and second collecting devices PCD1 and PCD2 may be disposed on the substrate SUB in the second chamber CM2. The first and second collecting devices PCD1 and PCD2 may collect the first and second particles PCT1 and PCT2 that may remain on the substrate SUB in the second chamber CM2.

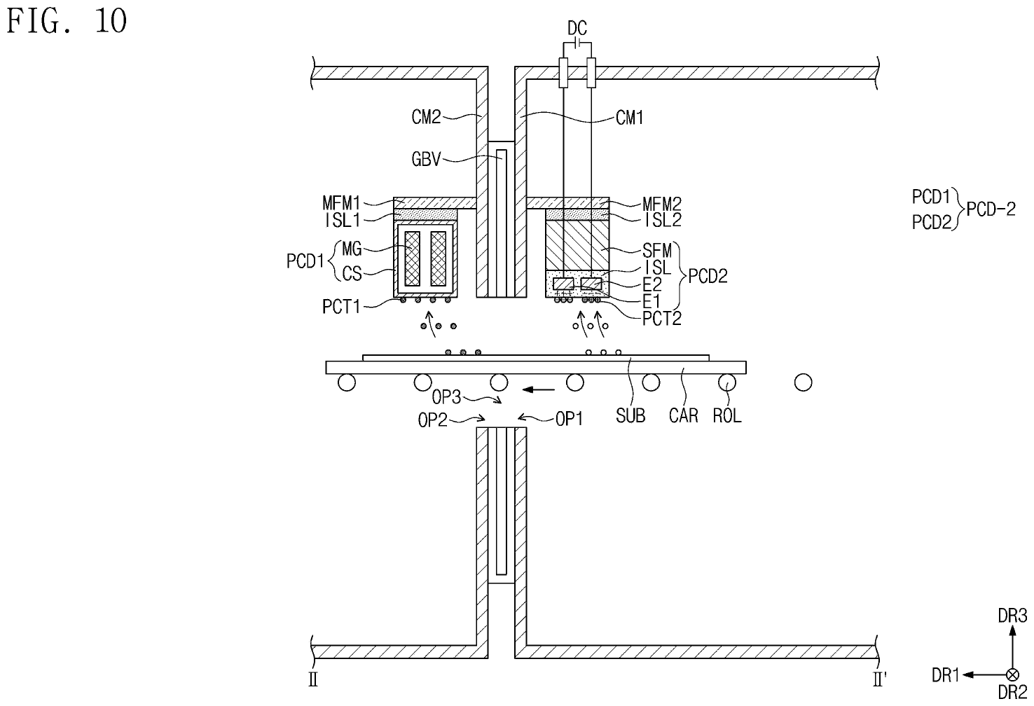

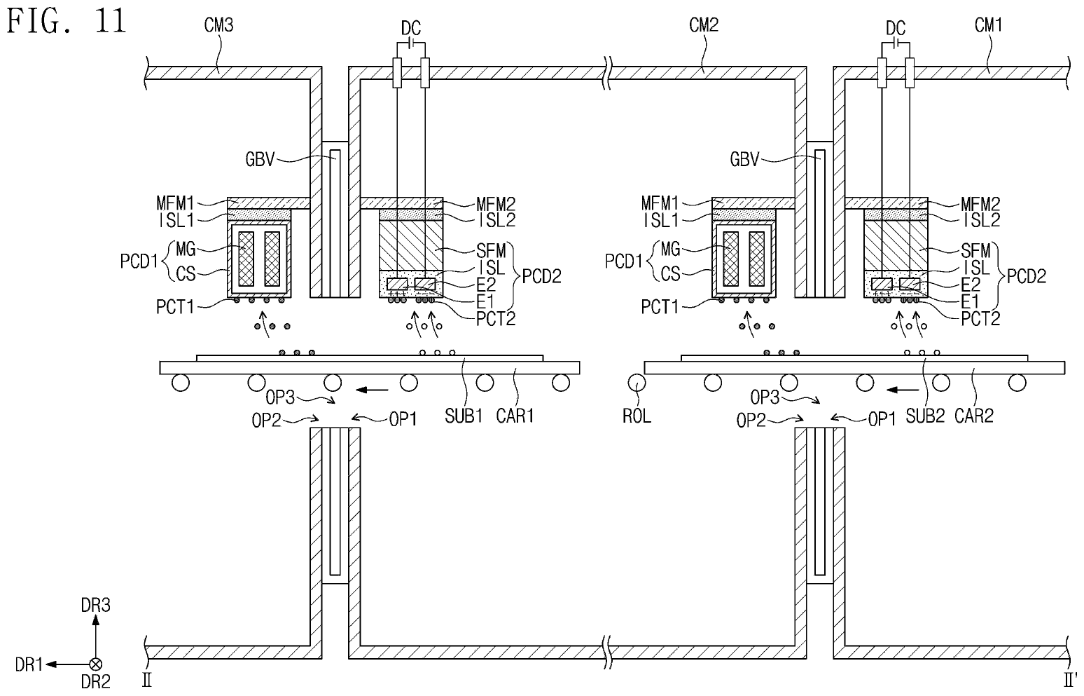

FIG. 10 is a diagram illustrating a configuration of a particle collecting device according to another embodiment of the present disclosure. FIG. 11 is a diagram in which the particle collecting devices illustrated in FIG. 10 are successively arranged in chambers.

FIG. 10 illustrates, as an example, a cross-section corresponding to that shown in FIG. 8, and thus, redundant description of the particle collecting device PCD-2 illustrated in FIG. 10 as that of the particle collecting device PCD illustrated in FIG. 8 may not be repeated, and the differences therebetween may be mainly described hereinafter.

Referring to FIG. 10, unlike the embodiment shown in FIG. 8, the substrate SUB may be transferred by a substrate carrier CAR. The substrate carrier CAR may be disposed in the first chamber CM1 and the second chamber CM2. The substrate carrier CAR may extend from the first chamber CM1 to the second chamber CM2 through the first, second, and third openings OP1, OP2, and OP3.

The substrate carrier CAR may move in the first direction DR1. The substrate carrier CAR may move from the first chamber CM1 to the second chamber CM2 through the first, second, and third openings OP1, OP2, and OP3.

A plurality of transfer rollers ROL may be disposed under (e.g., underneath) the substrate carrier CAR. A lower surface of the substrate carrier CAR may contact the transfer rollers ROL. While rotating in a counterclockwise direction, the transfer rollers ROL may transfer the substrate carrier CAR from the first chamber CM1 to the second chamber CM2.

The substrate SUB may be disposed on the substrate carrier CAR. The substrate carrier CAR may move in the first direction DR1, and thus, the substrate SUB may be transferred from the first chamber CM1 to the second chamber CM2 through the first, second, and third openings OP1, OP2, and OP3.

The particle collecting device PCD-2 may be separately disposed in the first chamber CM1 and in the second chamber CM2. For example, the second collecting device PCD2 may be disposed in the first chamber CM1, and the first collecting device PCD1 may be disposed in the second chamber CM2.

The particle collecting device PCD-2 may include a first main frame MFM1 disposed in the second chamber CM2, and a second main frame MFM2 disposed in the first chamber CM1. The first main frame MFM1 may be connected to the inner wall of the second chamber CM2 adjacent to the second opening OP2. The second main frame MFM2 may be connected to the inner wall of the first chamber CM1 adjacent to the first opening OP1.

A first insulating layer ISL1 may be disposed between the first main frame MFM1 and the first collecting device PCD1 in the second chamber CM2. A second insulating layer ISL2 may be disposed between the second main frame MFM2 and the second collecting device PCD2 in the first chamber CM1.

The first collecting device PCD1 may be disposed on the inner wall of the second chamber CM2 adjacent to the second opening OP2. The second collecting device PCD2 may be disposed on the inner wall of the first chamber CM1 adjacent to the first opening OP1.

When the substrate SUB is transferred from the first chamber CM1 to the second chamber CM2 by the substrate carrier CAR, the first collecting device PCD1 may be disposed on the substrate SUB in the second chamber CM2, and the second collecting device PCD2 may be disposed on the substrate SUB in the first chamber CM1. The first collecting device PCD1 may collect the first particles PCT1 that may remain on the substrate SUB in the second chamber CM2. The second collecting device PCD2 may collect the second particles PCT2 that may remain on the substrate SUB in the first chamber CM1.

Referring to FIG. 11, the first and second collecting devices PCD1 and PCD2 may be disposed in each of the chambers CM1, CM2, and CM3. For example, the first collecting device PCD1 and the second collecting device PCD2 may be disposed to be spaced apart from each other on inner walls of the second chamber CM2 in the second chamber CM2. In the second chamber CM2, the first collecting device PCD1 may be disposed on the inner wall of the second chamber CM2 adjacent to the first chamber CM1. In the second chamber CM2, the second collecting device PCD2 may be disposed on an inner wall of the second chamber CM2 adjacent to the third chamber CM3.

The first and second collecting devices PCD1 and PCD2 may be successively disposed in the first, second, and third chambers CM1, CM2, and CM3. A plurality of substrates SUB1 and SUB2 may be disposed on a plurality of substrate carriers CAR, and the substrate carriers CAR may be transferred in the first direction DR1 by the transfer rollers ROL. When the substrates SUB1 and SUB2 are transferred between the first, second, and third chambers CM1, CM2, and CM3, the first and second collecting devices PCD1 and PCD2 may collect the first and second particles PCT1 and PCT2 that may remain on the substrates SUB1 and SUB2.

According to one or more embodiments of the present disclosure, a particle collecting device for collecting particles that may remain on a substrate may be disposed on an inner wall of a chamber adjacent to an opening of the chamber. When the substrate is transferred through the opening, the particle collecting device may concurrently (e.g., simultaneously) collect metal particles and organic and/or inorganic particles disposed on the substrate. Accordingly, when a display panel is manufactured, a defect in the display panel may be prevented or substantially prevented.

Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A particle collecting device comprising:
a first collecting device configured to be located on a substrate transferred in a first direction, and extending in a second direction crossing the first direction; and
a second collecting device adjacent to the first collecting device in the first direction, the second collecting device configured to be located on the substrate, and extending in the second direction,
wherein the first collecting device is configured to collect a first particle remaining on the substrate, and
wherein the second collecting device is configured to collect a second particle remaining on the substrate, the second particle including a material different from that of the first particle.

2. The particle collecting device of claim 1, wherein:
the substrate is configured to be transferred from a first chamber to a second chamber adjacent to the first chamber;
an opening is defined in the first chamber, the opening being a path through which the substrate is transferred; and
the first and second collecting devices are located on an inner wall of the first chamber adjacent to the opening.

3. The particle collecting device of claim 2, wherein, when the substrate is transferred from the first chamber to the second chamber by a robot arm, the first and second collecting devices are configured to collect the first and second particles in the first chamber together.

4. The particle collecting device of claim 1, wherein the first collecting device is configured to generate a magnetic force.

5. The particle collecting device of claim 4, wherein the first particle comprises a metal particle.

6. The particle collecting device of claim 1, wherein the second collecting device is configured to generate an electrostatic force.

7. The particle collecting device of claim 6, wherein the second particle comprises an organic particle or an inorganic particle.

8. The particle collecting device of claim 1, further comprising a main frame, wherein the first and second collecting devices are located underneath the main frame.

9. The particle collecting device of claim 8, wherein the main frame comprises a metal.

10. The particle collecting device of claim 8, further comprising:
a first insulating layer between the main frame and the first collecting device; and
a second insulating layer between the main frame and the second collecting device.

11. The particle collecting device of claim 8, wherein the first collecting device comprises:
a case underneath the main frame; and
at least one magnet in the case.

12. The particle collecting device of claim 11, wherein the case comprises a metal.

13. The particle collecting device of claim 8, wherein the second collecting device comprises:
a sub frame underneath the main frame;
an insulating layer underneath the sub frame; and
a first electrode and a second electrode in the insulating layer, and configured to receive voltages of different polarities from each other.

14. The particle collecting device of claim 13, wherein the sub frame comprises a metal.

15. The particle collecting device of claim 13, further comprising a DC power supply configured to apply DC voltages to the first electrode and the second electrode.

16. The particle collecting device of claim 1, wherein:
the substrate is configured to be transferred from a first chamber to a second chamber adjacent to the first chamber;
an opening is defined in the second chamber, the opening being a path through which the substrate is transferred; and
the first and second collecting devices are located on an inner wall of the second chamber adjacent to the opening.

17. The particle collecting device of claim 1, wherein:
the substrate is configured to be transferred from a first chamber to a second chamber adjacent to the first chamber by a substrate carrier;
a first opening and a second opening are defined in the first chamber and the second chamber, respectively, the first opening and the second opening being paths through which the substrate is transferred; and
the first collecting device is located on an inner wall of the second chamber adjacent to the second opening, and the second collecting device is located on an inner wall of the first chamber adjacent to the first opening.

18. A deposition apparatus comprising:
a first chamber;
a second chamber adjacent to the first chamber;
a first collecting device configured to be located on a substrate transferred from the first chamber to the second chamber; and
a second collecting device configured to be located on the substrate, and adjacent to the first collecting device,
wherein an opening is defined in the first chamber, the opening being a path through which the substrate is transferred,
wherein the first and second collecting devices are located on an inner wall of the first chamber adjacent to the opening,
wherein the first collecting device is configured to collect a first particle remaining on the substrate, and
wherein the second collecting device is configured to collect a second particle remaining on the substrate, the second particle including a material different from that of the first particle.

19. The deposition apparatus of claim 18, wherein the first collecting device is configured to generate a magnetic force, and the first particle comprises a metal particle, and
wherein the second collecting device is configured to generate an electrostatic force, and the second particle comprises an organic particle or an inorganic particle.

20. The deposition apparatus of claim 19, wherein the first collecting device comprises:
a case; and
at least one magnet in the case, and
wherein the second collecting device comprises:
a sub frame:
an insulating layer underneath the sub frame; and
a first electrode and a second electrode in the insulating layer, the first electrode and the second electrode being configured to receive voltages of different polarities from each other.
